(19) United States
(12) Patent Application Publication
(10) Pub. No.: US 2026/0310021 A1
(43) Pub. Date: Oct. 8, 2026

(54) DISPLAY DEVICE

(71) Applicant: Wuhan China Star Optoelectronics Technology Co., Ltd., Wuhan (CN)

(72) Inventors: Xiaoyan ZUO, Wuhan (CN); Qunlong LIU, Wuhan (CN); Xiaolong WANG, Wuhan (CN); Wei ZHOU, Wuhan (CN); Xiang YANG, Wuhan (CN)

(73) Assignee: Wuhan China Star Optoelectronics Technology Co., Ltd., Wuhan (CN)

(21) Appl. No.: 18/227,946

(22) Filed: Jul. 30, 2023

Related U.S. Application Data
(63) Continuation of application No. PCT/CN2023/091522, filed on Apr. 28, 2023.

(30) Foreign Application Priority Data
Apr. 21, 2023 (CN) 202310439463.7

(51) Int. Cl. G02F 1/13357; F21V 8/00; G02F 1/1333; G02F 1/1335; H05K 1/189

(52) U.S. Cl. CPC G02F 1/13338; G02B 6/0091; G02F 1/133608; G02F 1/133612; H05K 1/189; H05K 2201/10136

(57) ABSTRACT

An embodiment of the present disclosure discloses a display device, wherein the display device includes a backlight module and a display panel. The backlight module includes a back frame and an optical film group. The display device further includes a signal synchronizing member positioned on a side of the optical film group away from the display panel, and at least a part of the signal synchronizing member is positioned between the back frame and the optical film group. The signal synchronizing member receives a first signal while the touch control function layer receives a touch control signal, and a voltage difference between the first signal and the touch control signal maintains constant.

### CROSS-REFERENCE TO RELATED APPLICATIONS

This application is a Continuation Patent Application of PCT Application No. PCT/CN2023/091522, filed Apr. 28, 2023, which claims the benefit of priority of Chinese Patent Application No. 202310439463.7, filed on Apr. 21, 2023. The contents of the above applications are all incorporated by reference as if fully set forth herein in their entirety.

### TECHNICAL FIELD

The present disclosure relates to a field of a display, and more particularly, to a display device.

### BACKGROUND

In recent years, screaming of a display device (such as a mobile phone) has become a difficult problem in display industry. By screaming, it is meant that when a person approaches his/her ear to a screen of the mobile phone, a flashing sound similar to an electric current is continuously heard. The person has different sensitivity to a low/high frequency of the flashing sound. film

### SUMMARY

The present disclosure provides a display device, and the display device includes: a backlight module, wherein the backlight module includes a back frame and an optical film group, the back frame has a receiving cavity, and the optical film group is positioned in the receiving cavity; a display panel, wherein the display panel is positioned on a light-emitting side of the backlight module, and the display panel includes a touch control function layer; and a signal synchronizing member, wherein the signal synchronizing member is positioned on a side of the optical film group away from the display panel, at least a part of the signal synchronizing member is positioned between the back frame and the optical film group; wherein the signal synchronizing member receives a first signal while the touch control function layer receives a touch control signal, and a voltage difference between the first signal and the touch control signal maintains constant.

In an embodiment, the back frame comprises a base plate and a first frame, the base plate is positioned on the side of the optical film group away from the display panel, and the first frame surrounds the base plate to define the receiving cavity; wherein the display device further comprises a first connecting member, a first end of the first connecting member is connected to the display panel, and a second end of the first connecting member is connected to a side of the base plate away from the optical film group; and wherein the signal synchronizing member is electrically connected to the first connecting member to obtain the first signal.

In an embodiment, the backlight module further comprises a light-guiding plate positioned on the side of the optical film group away from the display panel, and the signal synchronizing member is at least partially positioned between the light-guiding plate and the base plate; wherein the backlight module further comprises a light source, the light source is positioned on a side of the light-guiding plate close to the first frame.

In an embodiment, the backlight module further comprises a second connecting member, the second connecting member is positioned on a side of the light source away from the display panel, a first end of the second connecting member is extended through a first opening on the first frame to connect to the first connecting member, and a second end of the second connecting member is connected to the signal synchronizing member.

In an embodiment, the second connecting member is positioned between the light source and the signal synchronizing member.

In an embodiment, the first connecting member and the second connecting member are flexible printed circuits.

In an embodiment, the second connecting member is integrated with the signal synchronizing member.

In an embodiment, a first end of the signal synchronizing member is extended through a second opening on the first frame and is connected to a side of the first connecting member away from the base plate.

In an embodiment, the signal synchronizing member is a flexible printed circuit.

In an embodiment, the signal synchronizing member comprises a main body portion and a connecting portion, the main body portion is disposed in the receiving cavity to connect with the base plate, the connecting portion is extended through a second opening on the first frame and bent toward a side of the base plate away from the display panel, and the connecting portion is connected to the first connecting member.

In an embodiment, the connecting portion is a flexible printed circuit.

In an embodiment, the second connecting member comprises a first wiring layer and a second wiring layer, the second wiring layer is disposed on the first wiring layer, the signal synchronizing member and the first connecting member are electrically connected to the first wiring layer respectively, and the light source is electrically connected to the second wiring layer.

In an embodiment, the signal synchronizing member comprises a third wiring layer, the third wiring is electrically connected to the first connecting member to obtain the first signal.

In an embodiment, the connecting portion comprises a third wiring layer, the third wiring layer is electrically connected to the first connecting member to obtain the first signal.

In an embodiment, the display device further comprises an electromagnetic member, and the main body portion is integrated with the electromagnetic member.

In an embodiment, the electromagnetic member is an electromagnetic film between the light-guiding plate and the base plate.

In an embodiment, the third wiring layer is positioned on a side of the electromagnetic film close to the base plate.

In an embodiment, the voltage difference between the first signal and the touch control signal is 0.

In an embodiment, the display device further comprises a chip fixed to the display panel; wherein the chip is electrically connected to the touch control function layer, the chip is electrically connected to the first connecting member, and the touch control function layer obtains the touch control signal through the chip.

In an embodiment, the touch control functional layer is multiplexed as a common electrode layer of the display panel.

### BENEFICIAL EFFECT

The present disclosure makes the voltage difference between the first signal received by the signal synchronizing member and the touch control signal received by the touch function layer constant through the arrangement of the signal synchronizing member, reduces or eliminates the inverse piezoelectric effect of the optical film group between the signal synchronizing member and the touch function layer, and reduces or avoids the screaming caused by mechanical vibration of the film.

### BRIEF DESCRIPTION OF THE DRAWINGS

FIG. 1 is a structural schematic diagram of a display device according to related art;

FIG. 2 is a first structural schematic diagram of a display device according to an embodiment of the present disclosure;

FIG. 3 is a second structural schematic diagram of a display device according to an embodiment of the present disclosure;

FIG. 4 is a third structural schematic diagram of a display device according to an embodiment of the present disclosure;

FIG. 5 is a fourth structural schematic diagram of a display device according to an embodiment of the present disclosure;

FIG. 6 is a fifth structural schematic diagram of a display device according to an embodiment of the present disclosure;

FIG. 7a is a structural schematic diagram of wiring layers of a second connecting member according to an embodiment of the present disclosure, FIG. 7b is a structural schematic diagram of wiring layers of a signal synchronizing member according to an embodiment of the present disclosure; and

FIG. 8 is a structural schematic diagram of a signal synchronizing member according to an embodiment of the present disclosure.

### DETAILED DESCRIPTION OF THE EMBODIMENTS

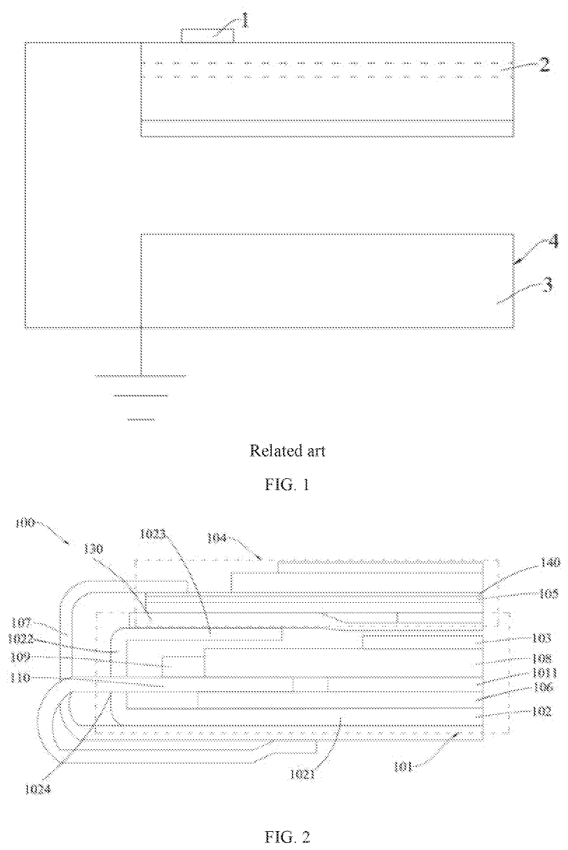

Currently, in a touch control operation of a touch display, an alternating scanning pulse signal sent by a touch control integrated circuit (IC) causes a pressure difference in a capacitor, formed by a back frame and a touch control function layer in a backlight module, to continuously change. A film in the backlight module continuously generates mechanical vibration to generate a screaming, which affects user experience. As shown in FIG. 1, a touch control IC 1 emits an alternating scanning pulse signal of a 0-3V voltage during a touch control operation of a touch control display. A back frame 4 and a touch control function layer 2 in a backlight module 3 are functioned respectively as two plates of a capacitor, and a film in the backlight module 3 is constantly subjected to a mechanical vibration due to a constant change in the pressure difference. As such, the screaming is generated.

The present disclosure provides a display device. The present disclosure will be described in further detail below with reference to the accompanying drawings and examples, in order to make the objects, technical solutions, and effects of the present disclosure clear and definite. It should be understood that the specific embodiments described herein are merely illustrative of the present disclosure and are not intended to limit the present disclosure.

Referring to FIS. 2 to FIG. 6, an embodiment of the present disclosure provides a display device 100. The display device 100 includes:
a backlight module 101, wherein the backlight module 101 includes a back frame 102 and an optical film group 103, the back frame 102 has a receiving cavity, and the optical film group 103 is positioned in the receiving cavity;
a display panel 104, wherein the display panel 104 is positioned on a light-emitting side of the backlight module 101, and the display panel 104 includes a touch control function layer 105; and
a signal synchronizing member 106, wherein the signal synchronizing member 106 is positioned on a side of the optical film group 103 away from the display panel 104, at least a part of the signal synchronizing member 106 is positioned between the back frame 102 and the optical film group 103;
wherein the signal synchronizing member 106 receives a first signal while the touch control function layer 105 receives a touch control signal, and a voltage difference between the first signal and the touch control signal maintains constant.

According to the embodiment of the present disclosure, by providing the signal synchronizing member 106, the voltage difference between the first signal received by the signal synchronizing member 106 and the touch control signal received by the touch function layer 105 maintains constant. As such, no electric potential difference is provided between the touch function layer 105 and the signal synchronizing member 106, and no capacitor is defined between the touch function layer 105 and the signal synchronizing member 106. Thus, the inverse piezoelectric effect of the optical film group 103 between the signal synchronizing member 106 and the touch function layer 105 is reduced or eliminated, and the screaming caused by mechanical vibration of the film is reduced or avoided.

The technical solution of the present disclosure will now be described with reference to specific examples.

Referring to FIG. 2 to FIG. 6, in an embodiment, the back frame 102 includes a base plate 1021 positioned on the side of the optical film group 103 away from the display panel 104, and a first frame 1022 surrounding the base plate 1021. The first frame 1022 surrounds the base plate 1021 to define the receiving cavity. The back frame 102 is made of metal. For example, the back frame 102 may be an iron frame, and the iron frame may be made, such as, by a sheet metal process in which the sheet metal material is suitable for stamping.

In an embodiment, the back frame 102 may further include a second frame 1023 positioned on a side of the first frame 1022 away from the base plate 1021. As shown in FIG. 2 to FIG. 6, the second frame 1023 extends transversely toward the optical film group 103 and surrounds the optical film group 103, and the second frame 1023 film supports the display panel 104. The display panel 104 may be adhered to the second frame 1023, for example, the display panel 104 may be adhered to the second frame 1023 by a lightproof adhesive tape 130. Alternatively, the backlight module 101 may further include a glue frame disposed on or in the back frame 102, and the glue frame is disposed around the optical film group 103. The glue frame may support the display panel 104, and the display panel 104 may be adhered to the glue frame, for example, the display panel 104 is adhered to the glue frame by a lightproof adhesive tape. The above description only describes several structures of the backlight module 101. In other embodiments of the present disclosure, the back frame 102 may be, for example, an integral rubber-iron frame, and the optical film group 103 and the integral rubber-iron frame may be assembled in other ways, which is not limited thereto.

In an embodiment, as shown in FIG. 2 to FIG. 6, the display device 100 further includes a first connecting member 107, wherein a first end of the first connecting member 107 is connected to the display panel 104, and a second end of the first connecting member 107 is connected to a side of the base plate 1021 away from the optical film group 103. The first connecting member 107 may be a flexible printed circuit (FPC), the display device 100 further includes a chip 140, and the chip 140 is coupled to the display panel 104. The first end of the first connecting member 107 is connected to the chip 140. The chip 140 is electrically connected to the touch function layer 105, and the touch function layer 105 obtains the touch control signal through the chip 140. Specifically, the touch function layer 105 includes a touch electrode, the chip 140 is electrically connected to the touch electrode, and the touch electrode obtains the touch control signal through the chip 140. The touch function layer 105 may be positioned on a side of a color film substrate 114 (referring to FIG. 6) of the display panel 104 away from the backlight module 101; alternatively, the touch function layer 105 may be multiplexed as a common electrode layer in the display panel 104.

In an embodiment, the chip 140 may be a touch and display diver Integration (TDDI) chip, and referring to FIG. 6, the touch electrode may be a common electrode on the array substrate 113 or the color film substrate 114 in the display panel 104. The TDDI chip uses a method of time division multiplexing to provide a common signal to the common electrode when the display panel 104 is used for display, and to provide the touch control signal to the touch electrode when the display panel 104 is used for touch.

In an embodiment, the optical film group 103 may include a plurality of optical sub-films, for example, the optical film group 103 may include a first optical sub-film, a second optical sub-film, and a third optical sub-film sequentially stacked along a direction from the base plate 1021 to the display panel 104. The first optical sub-film may be a diffusion sheet, which is also referred to as a diffusion plate or a diffusion film for providing a uniform area light for the display panel 104. The second optical sub-film may be a lower brightness enhancement film, the third optical sub-film sheet may be an upper brightness enhancement film, and the brightness enhancement films are used to improve the luminous efficiency of the backlight module 101. The upper brightness enhancement film and the lower brightness enhancement film may be selected from one or more of a general prism sheet, a multifunctional prism sheet, a micro-lens film, or a reflective polarizer.

In an embodiment, as shown in FIG. 2 to FIG. 5, the backlight module 101 further includes a light-guiding plate 108 positioned on a side of the optical film group 103 away from the display panel 104, and the signal synchronizing member 106 is positioned at least partially between the light-guiding plate 108 and the base plate 1021. The backlight module 101 further includes a light source 109 and a second connecting member 110, wherein the light source 109 is positioned on a side of the light-guiding plate 108 close to the first frame 1022, and the second connecting member 110 is positioned on a side of the light source 109 away from the display panel 104.

In an embodiment, the light-guiding plate 108 may be wedge-shaped plate or plate-shaped, and the light source 109 may be a light-emitting diode (LED), a micro light-emitting diode (Micro LED) or a mini light-emitting diode (Mini LED).

In an embodiment, an orthographic projection of the light source 109 on the base plate 1021 is in an orthographic projection of the second frame 1023 of the back frame 102 on the base plate 1021, and an orthographic projection of the light-guiding plate 108 on the base plate 1021 is at least partially in the orthographic projection of the second frame 1023 of the back frame 102 on the base plate 1021. Alternatively, the orthographic projection of the light source 109 on the base plate 1021 is in the orthographic projection of the second frame 1023 of the back frame 102 on the base plate 1021. An orthographic projection of the optical film group 103 on the base plate 1021 is in an orthographic projection of the lightproof adhesive tape 130 on the base plate 1021 to reduce or eliminate light leakage of the display device 100 in a non-display area.

In an embodiment, the backlight module 101 further includes a reflective sheet 1011 positioned between the light-guiding plate 108 and the base plate 1021 for increasing light utilization of the backlight module 101. The signal synchronizing member 106 is partially positioned between the base plate 1021 and the reflective sheet 1011.

As shown in FIG. 2, in an embodiment, the first frame 1022 includes a first opening 1024. A first end of the second connecting member 110 is extended through the first opening 1024 and bent toward a side of the base plate 1021 away from the display panel 104 to connect to a side of the first connecting member 107 away from the base plate 1021. That is, the first end of the second connecting member 110 is extended through the first opening 1024 and bent to the side of the base plate 1021 away from the display panel 104, and the first end of the second connecting member 110 is connected to the side of the first connecting member 107 away from the display panel 104. The second connecting member 110 may be a flexible printed circuit.

Referring to FIG. 2, the light source 109 is connected to a side of the second connecting member 110 away from the base plate 1021, and the signal synchronizing member 106 is connected to a side of the second connecting member 110 close to the base plate 1021. That is, the second connecting member 110 is positioned between the light source 109 and the signal synchronizing member 106. In an embodiment, the first end of the second connecting member 110 is connected to the first connecting member 107 through a first pad, and the first pad is provided on the first connecting member 107. The second end of the second connecting member 110 is electrically connected to the signal synchronizing member 106. As such, the signal synchronizing member 106 is electrically connected to the first connecting member 107 to obtain the first signal.

In an embodiment, as shown in FIG. 2, the signal synchronizing member 106 is positioned between the light-guiding plate 108 and the base plate 1021, the second connecting member 110 is connected on the signal synchronizing member 106, and the light source 109 is connected on the second connecting member 110. Referring to FIG. 7a, the second connecting member 110 includes a first wiring layer 112a, a first substrate 119a and a second wiring layer 121a, wherein the first wiring layer 112a and the second wiring layer 121a are positioned on respective side of the first substrate 119a, and the first wiring layer 112a is positioned on a side of the first substrate 119a close to the base plate 1021. The first wiring layer 112a includes a first wiring, and the second wiring layer 121a includes a second wiring. Referring to FIG. 7b, the signal synchronizing member 106 includes a second substrate 119b and a third wiring layer 112b stacked toward a side away from the base plate 1021. The third wiring layer 112b includes a third wiring. The first wiring layer112a is electrically connected to the first connecting member 107 and the signal synchronizing member 106, respectively. Specifically, the first wiring is electrically connected to the third wiring, so that the first wiring layer112a is electrically connected to the signal synchronizing member 106. Further, the first wiring is electrically connected to the first connecting member 107, so that the first wiring layer 112a is electrically connected to the first connecting member 107. As such, the third wiring is electrically connected to the first connecting member 107 through the first wiring, and the signal synchronizing member 106 obtains the first signal from the first connecting member 107. The third wiring is electrically connected to the first wiring by a second pad, the second pad may be disposed on a side of the second connecting member 110 close to the base plate 1021, or the second pad may be disposed on a side of the signal synchronizing member 106 away from the base plate 1021. The second wiring layer 121a is positioned on the side of the first substrate 119a away from the base plate 1021, the light source 109 is electrically connected to the second wiring, and the second wiring is electrically connected to the first connecting member 107. As such, the first connecting member 107 transmits a driving signal to the light source 109 through the second wiring, thereby controlling the light source 109. The first wiring is electrically connected to the first connecting member 107 through a third pad, and the third pad may be provided on the first connecting member 107. The first wiring layer 112a and the second wiring layer 121a are provided on respective side of the first substrate 119a, so that the first wiring and the second wiring do not interfere with each other, thereby reducing or eliminating the risk of short circuit and improving the display quality of the display device 100.

The material of the first substrate may be a flexible material, such as polyimide or the like. The material of the first wiring may be a conductive material; such as copper or the like. The material of the second substrate may be the same as the material of the first substrate. The material of the second wiring and the material of the third wiring may be the same as the material of the first wiring.

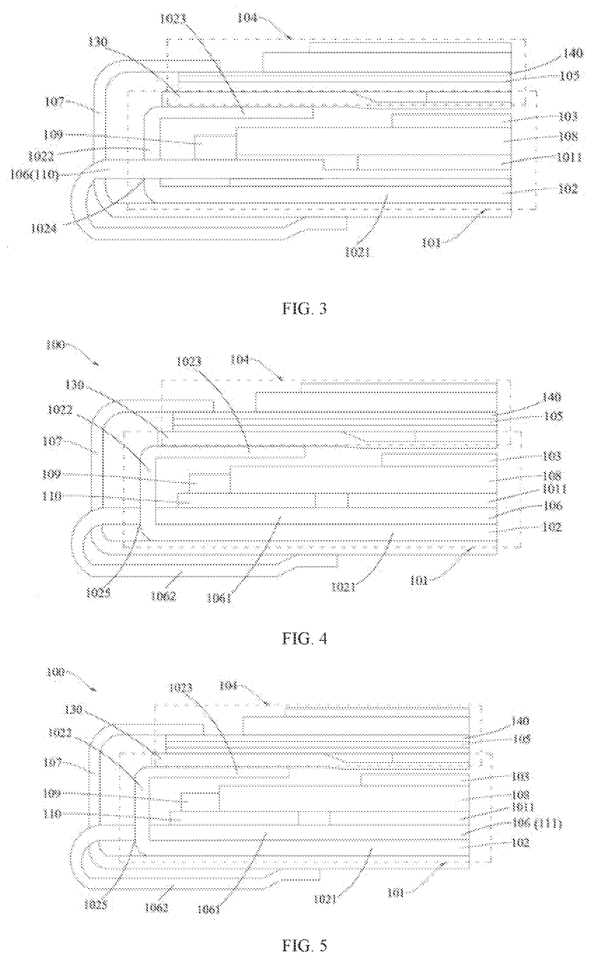

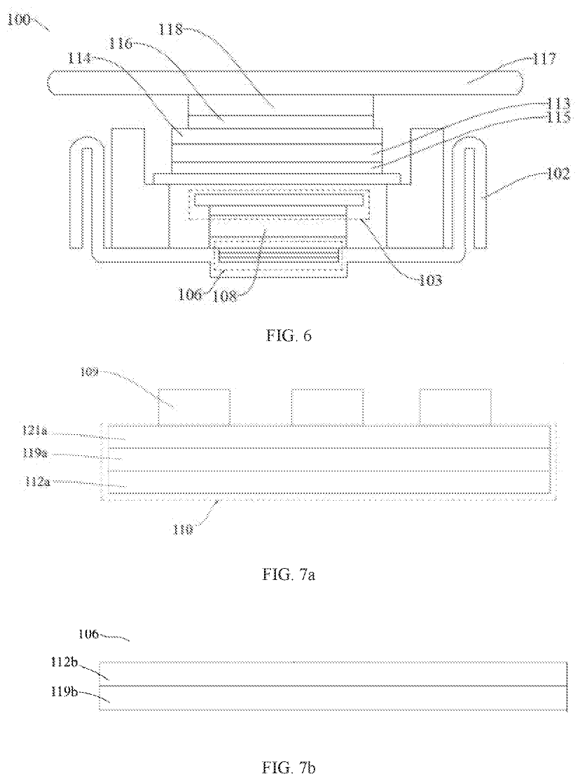

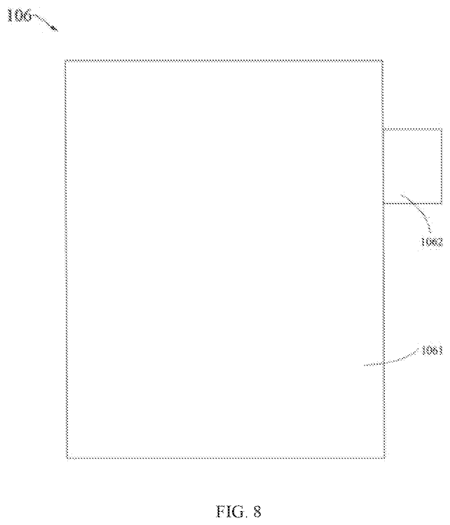

Referring to FIG. 3, in an embodiment, in a case that the signal synchronizing member 106 is a flexible printed circuit, the second connecting member 110 is integrated with the signal synchronizing member 106. In this case, combined with FIG. 7(a) and 7(b), the third wiring layer 112b may be integrated with the first wiring layer 112a, the third wiring is positioned close to the base plate 1021, and the third wiring is electrically connected to the first connecting member 107 to obtain the first signal. The second wiring is positioned away from the base plate 1021, and the second wiring is electrically connected to the first connecting member 107 so that the light source 109 obtains a driving signal. The integration of the second connecting member 110 and the signal synchronizing member 106 advantageously reduces the provision of redundant components and saves processing costs.

Referring to FIG. 4, in an embodiment, a first end of the signal synchronizing member 106 is extended through a second opening 1025 on the first frame 1022 and is connected to a side of the first connecting member 107 away from the base plate 1021. The second opening 1025 may be the first opening 1024 2 or different from the first opening 1024. The signal synchronizing member 106 includes a first portion positioned in the receiving cavity, and a second portion is positioned outside the receiving cavity. The first portion may be partially positioned between the second connecting member 110 and the base plate 1021. In a case that the backlight module 101 includes the reflective sheet 1011, the first portion may be partially positioned between the reflective sheet 1011 and the base plate 1021. The first portion may be secured to a side of the base plate 1021 close to the optical film group 103 by an adhesive tape. The signal synchronizing member 106 may further include a third substrate positioned on a side of the third wiring layer 112b away from the base plate 1021, and the second substrate 119b and the third substrate are disposed on respective side of the third wiring layer 112b, so as to advantageously reduce or avoid damage to the third wiring, and improve the product quality of the display device 100.

In an embodiment, as shown in FIG. 4 and FIG. 8, the signal synchronizing member 106 includes a main body portion 1061 and a connecting portion 1062, wherein the connecting portion 1062 is extended through the second opening 1025 and bent toward a side of the base plate 1021 away from the display panel 104. A first end of the connecting portion 1062 is connected to the first connecting member 107, and a second end of the connecting portion 1062 is connected to the main body portion 1061. The connecting portion 1062 may be a flexible printed circuit, the connecting portion 1062 includes a fourth wiring, the third wiring is electrically connected to the fourth wiring, and the fourth wiring is electrically connected to the first connecting member 107, so that the signal synchronizing member 106 obtains the first signal. The third wiring and the fourth wiring may be electrically connected by a fourth pad, the fourth pad may be positioned at the connecting portion 1062, or the fourth pad may be positioned at the main body portion 1061. The fourth wiring may be electrically connected to the first connection member 107 through a fifth pad, and the fifth pad may be positioned at the first connecting member 107, or the fifth pad may be positioned at the connecting portion 1062. By providing the main body portion 1061 and the connecting portion 1062, the connecting portion 1062 is connected between the main body portion 1061 and the first connecting member 107, thereby reducing bending stress of the main body portion 1061 and improving product quality of the display device 100.

Referring to FIG. 5, the display device 100 further includes an electromagnetic member 111, and the main body portion 1061 of the signal synchronizing member 106 is integrated with the electromagnetic member 111. The electromagnetic member 111 may be an electromagnetic film positioned between the light-guiding plate 108 and the base plate 1021, and the third wiring layer 112b is positioned on a side of the electromagnetic film close to the base plate 1021. The electromagnetic film performs a writing function by cooperating with a stylus. An orthographic projection of the display panel 104 on the base plate 1021 is in an orthographic projection of the electromagnetic film on the base plate 1021 to lead the display panel 104 to have an overall electromagnetic input function, depending on the use requirements. Alternatively, the orthographic projection of the display panel 104 on the base plate 1021 is partially in the orthographic projection of the electromagnetic film on the base plate 1021, so that a specific area of the display panel 104 has an electromagnetic input function. By providing the signal synchronizing member 106 integrally with the electromagnetic member 111, it is advantageous to reduce the provision of redundant components and to save processing costs.

In the present embodiment, while the touch control function layer 105 receives the touch control signal, the signal synchronizer 106 receives the first signal, and the voltage difference between the touch control signal and the first signal maintains constant. That is, the voltage of the touch control electrode and the voltage of the third wiring of the signal synchronizer member are consistent, thereby reducing or eliminating the inverse piezoelectric effect of the optical film group 103 between the signal synchronizer 106 and the touch control function layer 105, and reducing or avoiding the screaming caused by mechanical vibration of the film. The touch control signal may be a touch scan signal, the touch control signal may be a pulse signal, and the first signal may also be a pulse signal.

In an embodiment, the first connecting member 107 includes a fifth wiring, the third wiring is electrically connected to the fifth wiring, and the fifth wiring is electrically connected to the chip. While the chip supplies the touch control signal to the touch function layer 105, the chip supplies the first signal to the third wiring through the fifth wiring, thereby synchronizing the first signal with the touch control signal.

In an embodiment, the voltage difference between the touch control signal and the first signal is 0, thus, in the direction from the display panel 104 to the back frame 102, no voltage difference is provided to the optical film group 103 positioned between the signal synchronizer 106 and the touch function layer 105, thereby reducing or eliminating the inverse piezoelectric effect experienced by the optical film group 103, and further attenuating or avoiding the screaming caused by mechanical vibration of the film.

Referring to FIG. 6, in an embodiment, the display panel 104 includes an array substrate 113, a color film substrate 114 and a liquid crystal layer, wherein the array substrate 113 and the color film substrate 114 are oppositely disposed, and the liquid crystal layer is disposed between the array substrate 113 and the color film substrate 114. The chip is disposed to the array substrate 113. The color film substrate 114 is positioned on a side of the array substrate 113 away from the backlight module 101. The display panel 104 further includes a first polarizer 115 positioned on a side of the array substrate 113 close to the backlight module 101, and a second polarizer 116 positioned on a side of the color film substrate 114 away from the backlight module 101. The display device 100 further includes a cover plate 117 on a side of the second polarizer 116 away from the backlight module 101, and the cover plate 117 is adhesively fixed to the second polarizer 116 by an optical adhesive layer 118.

In an embodiment, the array substrate 113 includes a fourth substrate, an active layer on the fourth substrate, a first insulating layer on the active layer, a gate layer on the first insulating layer, a second insulating layer on the gate layer, a source drain layer on the second insulating layer, and a third insulating layer on the source drain layer, wherein the source drain layer includes a source and a drain. The array substrate 113 further includes a common electrode layer on the third insulating layer, a fourth insulating layer on the common electrode layer, and a pixel electrode layer on the fourth insulating layer. Alternatively, the array substrate 113 further includes a pixel electrode layer on the third insulating layer, a fifth insulating layer on the pixel electrode layer, and a common electrode layer on the fifth insulating layer. Alternatively, the array substrate 113 further includes a pixel electrode layer on the third insulating layer, and the color film substrate 114 includes a common electrode layer close to a side of the array substrate 113. The common electrode layer includes a common electrode that may be multiplexed as the touch electrode. The common electrode is arranged in a whole layer, and the common electrode is arranged in a block shape.

According to the display device 100 disclosed in the embodiment of the present disclosure, the voltage difference between the first signal received by the signal synchronizing member 106 and the touch control signal received by the touch function layer 105 maintains constant by the arrangement of the signal synchronizing member 106, the inverse piezoelectric effect of the optical film group 103 between the signal synchronizing member 106 and the touch function layer 105 is reduced or eliminated, and the screaming caused by mechanical vibration of the film is reduced or avoided.

An embodiment of the present disclosure discloses a display device including a backlight module, and a display panel positioned on a light-emitting side of the backlight module. The backlight module includes a back frame and an optical film group, and the optical film group is positioned in a receiving cavity defined by the back frame. The display device further includes a signal synchronizing member positioned on a side of the optical film group away from the display panel, and the signal synchronizing member is positioned at least partially between the back frame and the optical film group. The signal synchronizing member receives a first signal while the touch control function layer of the display panel receives a touch control signal, and the voltage difference between the touch control signal and the first signal maintains constant. The screaming caused by mechanical vibration of the film is attenuated or avoided.

It should be understood by those of ordinary skill in the art that equivalents may be substituted or varied in accordance with the technical solution of the present disclosure and its inventive concept, and all such variations or substitutions are intended to fall within the scope of the claims appended hereto.

What is claimed is:

1. A display device, comprising:
a backlight module, wherein the backlight module includes a back frame and an optical film group, the back frame has a receiving cavity, and the optical film group is positioned in the receiving cavity;
a display panel, wherein the display panel is positioned on a light-emitting side of the backlight module, and the display panel includes a touch control function layer; and
a signal synchronizing member, wherein the signal synchronizing member is positioned on a side of the optical film group away from the display panel, at least a part of the signal synchronizing member is positioned between the back frame and the optical film group;
wherein the signal synchronizing member receives a first signal while the touch control function layer receives a touch control signal, and a voltage difference between the first signal and the touch control signal maintains constant.

2. The display device of claim 1, wherein the back frame comprises a base plate and a first frame, the base plate is positioned on the side of the optical film group away from the display panel, and the first frame surrounds the base plate to define the receiving cavity;
wherein the display device further comprises a first connecting member, a first end of the first connecting member is connected to the display panel, and a second end of the first connecting member is connected to a side of the base plate away from the optical film group; and
wherein the signal synchronizing member is electrically connected to the first connecting member to obtain the first signal.

3. The display device of claim 2, wherein the backlight module further comprises a light-guiding plate positioned on the side of the optical film group away from the display panel, and the signal synchronizing member is at least partially positioned between the light-guiding plate and the base plate;
wherein the backlight module further comprises a light source, the light source is positioned on a side of the light-guiding plate close to the first frame.

4. The display device of claim 3, wherein the backlight module further comprises a second connecting member, the second connecting member is positioned on a side of the light source away from the display panel, a first end of the second connecting member is extended through a first opening on the first frame to connect to the first connecting member, and a second end of the second connecting member is connected to the signal synchronizing member.

5. The display device of claim 4, wherein the second connecting member is positioned between the light source and the signal synchronizing member.

6. The display device of claim 5, wherein the first connecting member and the second connecting member are flexible printed circuits.

7. The display device of claim 6, wherein the second connecting member is integrated with the signal synchronizing member.

8. The display device of claim 4, wherein a first end of the signal synchronizing member is extended through a second opening on the first frame and is connected to a side of the first connecting member away from the base plate.

9. The display device of claim 8, wherein the signal synchronizing member is a flexible printed circuit.

10. The display device of claim 4, wherein the signal synchronizing member comprises a main body portion and a connecting portion, the main body portion is disposed in the receiving cavity to connect with the base plate, the connecting portion is extended through a second opening on the first frame and bent toward a side of the base plate away from the display panel, and the connecting portion is connected to the first connecting member.

11. The display device of claim 10, wherein the connecting portion is a flexible printed circuit.

12. The display device of claim 7, wherein the second connecting member comprises a first wiring layer and a second wiring layer, the second wiring layer is disposed on the first wiring layer, the signal synchronizing member and the first connecting member are electrically connected to the first wiring layer respectively, and the light source is electrically connected to the second wiring layer.

13. The display device of claim 9, wherein the signal synchronizing member comprises a third wiring layer, the third wiring is electrically connected to the first connecting member to obtain the first signal.

14. The display device of claim 11, wherein the connecting portion comprises a third wiring layer, the third wiring layer is electrically connected to the first connecting member to obtain the first signal.

15. The display device of claim 13, wherein the display device further comprises an electromagnetic member, and a main body portion of the signal synchronizing member is integrated with the electromagnetic member.

16. The display device of claim 15, wherein the electromagnetic member is an electromagnetic film between the light-guiding plate and the base plate.

17. The display device of claim 16, wherein the third wiring layer is positioned on a side of the electromagnetic film close to the base plate.

18. The display device of claim 1, wherein the voltage difference between the first signal and the touch control signal is 0.

19. The display device of claim 1, wherein the display device further comprises a chip fixed to the display panel;
wherein the chip is electrically connected to the touch control function layer, the chip is electrically connected to the first connecting member, and the touch control function layer obtains the touch control signal through the chip.

20. The display device of claim 19, wherein the touch control functional layer is multiplexed as a common electrode layer of the display panel.
